(19) United States
(12) Patent Application Publication
(10) Pub. No.: US 2026/0319302 A1
(43) Pub. Date: Oct. 15, 2026

(54) MASK AND DISPLAY PANEL

(71) Applicants: Fuzhou BOE Optoelectronics Technology Co., Ltd., Fuzhou, Fujian (CN); BOE Technology Group Co., Ltd., Beijing (CN)

(72) Inventors: Wenchao Wang, Beijing (CN); Xin Fang, Beijing (CN); Longgan Hu, Beijing (CN); Xiaolong Chen, Beijing (CN)

(73) Assignees: Fuzhou BOE Optoelectronics Technology Co., Ltd., Fuzhou, Fujian (CN); BOE Technology Group Co., Ltd., Beijing (CN)

(21) Appl. No.: 19/483,704

(22) PCT Filed: Apr. 18, 2024
(86) PCT No.: PCT/CN2024/088664

§ 371 Date: Nov. 12, 2025

(30) Foreign Application Priority Data
May 31, 2023 (CN) 202310635866.9

(51) Int. Cl. G02F 1/1362

(52) U.S. Cl. CPC G02F 1/13625; G02F 1/136204; G02F 1/136209; G02F 1/136222

(57) ABSTRACT

A mask includes: a transparent substrate; and a light-shielding layer provided on one side of the transparent substrate, and including a first conductive pattern, a second conductive pattern, and an electrostatic discharge line, wherein a hollow-out area is provided between the first conductive pattern and the second conductive pattern, and the electrostatic discharge line is positioned in the hollow-out area; and one side of the first conductive pattern facing the second conductive pattern includes a first edge and a second edge, the first edge and the second edge are connected to form a first concave angle, a first end of the electrostatic discharge line is electrically connected to the first concave angle, and a second end of the electrostatic discharge line is electrically connected to the second conductive pattern.

### CROSS-REFERENCE TO RELATED APPLICATION

The disclosure claims the priority of the Chinese patent application filed on May 31, 2023 before the CNIPA, China National Intellectual Property Administration with the application number of 202310635866.9 and the title of “MASK AND DISPLAY PANEL”, which is incorporated herein in its entirety by reference.

### FIELD

The disclosure relates to the technical field of display panel preparation, and more particularly, to a mask and a display panel.

### BACKGROUND

With advancements in technology, the spacing between two adjacent patterned structures in a display panel has gradually decreased. Correspondingly, the distance between two adjacent light-shielding patterns in a light-shielding layer of a mask has also gradually decreased. Since the light-shielding patterns are typically made of conductive materials, when the spacing between two adjacent light-shielding patterns is excessively small, point discharge is likely to occur, thereby resulting in damage to edges of the light-shielding patterns.

### SUMMARY

Embodiments of the disclosure provide a mask and a display panel, wherein point discharge is not likely to occur on a light-shielding layer.

In order to achieve the above object, the following technical solution is adopted in the embodiments of the disclosure:
in an aspect, a mask is provided, including:
a transparent substrate; and
a light-shielding layer provided on one side of the transparent substrate, and including a first conductive pattern, a second conductive pattern, and an electrostatic discharge line, wherein a hollow-out area is provided between the first conductive pattern and the second conductive pattern, and the electrostatic discharge line is positioned in the hollow-out area; and one side of the first conductive pattern facing the second conductive pattern includes a first edge and a second edge, the first edge and the second edge are connected to form a first concave angle, a first end of the electrostatic discharge line is electrically connected to the first concave angle, and a second end of the electrostatic discharge line is electrically connected to the second conductive pattern.

In some implementations, wherein the first end of the electrostatic discharge line extends along an angular bisector of the first concave angle.

In some implementations, wherein the first concave angle is provided with a first notch, a partial area of the first end of the electrostatic discharge line is positioned in the first notch, and a gap is provided between the electrostatic discharge line and a side edge of the first notch.

In some implementations, wherein a partial or entire area of the first notch is positioned on sides of the first edge and the second edge away from the hollow-out area.

In some implementations, wherein the side edge of the first notch includes a first side edge and a second side edge, the first side edge and the second side edge are provided parallel and opposite to each other, and the first end of the electrostatic discharge line is positioned between the first side edge and the second side edge; and the first notch further includes a first bottom edge and a second bottom edge, the first bottom edge is connected to the first side edge and the electrostatic discharge line, the first bottom edge is parallel to the first edge, the second bottom edge is connected to the second side edge and the electrostatic discharge line, and the second bottom edge is parallel to the second edge.

In some implementations, wherein the first notch includes the first side edge and the second side edge, a first gap is enclosed by the first side edge and the electrostatic discharge line, a second gap is enclosed by the second side edge and the electrostatic discharge line, and the first gap and/or the second gap is not communicated with the hollow-out area.

In some implementations, wherein the first notch is quadrilateral, and a diagonal line of the first notch coincides with the angular bisector of the first concave angle.

In some implementations, wherein a partial or entire area of the first notch is positioned on sides of the first edge and the second edge close to a transparent area.

In some implementations, wherein the first edge is provided with a first protrusion protruding towards the hollow-out area, the second edge is provided with a second protrusion protruding towards the hollow-out area, and the first notch is enclosed by the first protrusion and the second protrusion.

In some implementations, wherein the first notch is symmetrically provided relative to the angular bisector of the first concave angle.

In some implementations, wherein a light-shielding portion is provided in the gap, and the light-shielding portion is island-shaped in the gap.

In some implementations, wherein the electrostatic discharge line includes a first wire, a second wire, and a transition line connecting the first wire to the second wire, the first wire extends along a first direction, the second wire extends along a second direction, the first direction intersects the second direction, and a line width of the transition line is equal to a line width of the first wire and the second wire.

In some implementations, wherein the transition line is an arc.

In some implementations, wherein one side of the second conductive pattern facing the first conductive pattern includes a third edge and a fourth edge, the third edge and the fourth edge are connected to form a second concave angle, and the second end of the electrostatic discharge line is electrically connected to the second concave angle.

In some implementations, wherein a straight-line distance between the first concave angle and the second concave angle is greater than or equal to 10 μm.

In some implementations, wherein a line width of the electrostatic discharge line is L, and 0.5 μm≤L≤1.0 μm.

In some implementations, wherein the first conductive pattern includes a first conductive portion protruding towards the second conductive pattern, the second conductive pattern includes a second conductive portion, the first conductive portion is directly opposite to the second conductive portion, a minimum distance between the first conductive portion and the second conductive portion is d, and a width of the first conductive portion along a direction perpendicular to the minimum distance between the first conductive portion and the second conductive portion is w; and d≤10 μm, and w≤500 μm.

In some implementations, wherein the electrostatic discharge line is provided close to an edge of the mask.

In another aspect, a display panel is provided, and the display panel includes a plurality of film layers, wherein at least one of the plurality of film layers is fabricated by photolithography using the mask.

The mask and the display panel provided in the embodiments of the disclosure, the light-shielding layer includes the first conductive pattern, the second conductive pattern, and the electrostatic discharge line, wherein the hollow-out area is provided between the first conductive pattern and the second conductive pattern, and the electrostatic discharge line is positioned in the hollow-out area; and one side of the first conductive pattern facing the second conductive pattern includes the first edge and the second edge, the first edge and the second edge are connected to form the first concave angle, the first end of the electrostatic discharge line is electrically connected to the first concave angle, and the second end of the electrostatic discharge line is electrically connected to the second conductive pattern. A patterned structure formed by transferring the first conductive pattern to a photoresist layer is a first patterned structure. Since the electrostatic discharge line is electrically connected to the first concave angle, a first residual structure formed corresponding to a joint of the electrostatic discharge line and the first conductive pattern in the first patterned structure is positioned in an area opposite to the first concave angle; and due to the exposure characteristic inherent to the first concave angle, a second residual part may be formed in the area opposite to the first concave angle in the first patterned structure. That is, both the first residual part and the second residual part are positioned in the area opposite to the first concave angle in the first patterned structure, so that at least partial areas of the first residual part and the second residual part coincide with each other, thereby decreasing a quantity of the residual parts, and reducing the impact on the patterned structure.

### BRIEF DESCRIPTION OF THE DRAWINGS

In order to more clearly illustrate the technical solutions in the embodiments of the present disclosure or in the prior art, the accompanying drawings required for describing the embodiments or the prior art will be briefly introduced below. It is obvious that the drawings described below are only some embodiments of the present disclosure, and those skilled in the art can also obtain other drawings based on these drawings without any creative effort.

FIG. 1 schematically shows a front-view structure of a display device;

FIG. 2 schematically shows a cross-sectional diagram of a mask;

FIG. 3 is a partial schematic diagram of a display panel in the related art;

FIG. 4 is a partial schematic diagram of the display panel in the related art;

FIG. 5 is a partial schematic diagram of a photoresist layer in related art;

FIG. 6 schematically shows a partial plan diagram of a light-shielding layer;

FIG. 7 schematically shows a partial plan diagram of another light-shielding layer;

FIG. 8 schematically shows a plan diagram of another light-shielding layer;

FIG. 9 schematically shows a plan diagram of an electrostatic discharge line;

FIG. 10 schematically shows a plan diagram of another electrostatic discharge line;

FIG. 11 schematically shows a plan diagram of another electrostatic discharge line;

FIG. 12 schematically shows a partial structural diagram of a light-shielding layer;

FIG. 13 schematically shows a patterned structure formed by transferring a first conductive pattern to the photoresist layer;

FIG. 14 schematically shows a first patterned structure formed after a first end of the electrostatic discharge line is connected to a first concave angle;

FIG. 15 schematically shows a partial structural diagram of the first conductive pattern;

FIG. 16 schematically shows a partial structural diagram of the first conductive pattern;

FIG. 17 shows a structural diagram of the first conductive pattern without the electrostatic discharge line connected;

FIG. 18 schematically shows a partial structural diagram of the first conductive pattern;

FIG. 19 schematically shows a partial structural diagram of the first conductive pattern;

FIG. 20 schematically shows a partial plan diagram of another light-shielding layer;

FIG. 21 schematically shows a partial plan diagram of another light-shielding layer;

FIG. 22 schematically shows a display panel;

FIG. 23 schematically shows a partial structure of an area corresponding to a GP side in the light-shielding layer;

FIG. 24 schematically shows a partial structure of an area corresponding to a scanning circuit output line in the light-shielding layer;

FIG. 25 schematically shows a partial structure diagram of an area corresponding to a DP side in the light-shielding layer; and FIG. 26 schematically shows a partial structure diagram of an area corresponding to a DPO side in the light-shielding layer.

### DETAILED DESCRIPTION

The technical solutions in the embodiments of the present disclosure will be described clearly and completely below with reference to the accompanying drawings in the embodiments of the present disclosure. It is apparent that the described embodiments are only some, rather than all, of the embodiments of the present disclosure. All other embodiments obtained by those of ordinary skill in the art based on the embodiments in the present disclosure without creative efforts shall fall within the protection scope of the present disclosure.

In the embodiments of the present disclosure, terms such as “first,” “second,” “third,” and “fourth” are used merely to distinguish the same or similar items that have substantially the same function or effect, so as to clearly describe the technical solutions of the embodiments in the present disclosure. Such terms shall not be understood as indicating or implying relative importance or implicitly specifying the number of indicated technical features.

In the embodiments of the present disclosure, “a plurality of” means two or more, and “at least one” means one or more, unless otherwise expressly and specifically defined.

In the embodiments of the present disclosure, directional or positional terms such as “upper” and “lower” are defined with reference to the orientations or positions shown in the accompanying drawings, and are used only to facilitate and simplify the description of the present disclosure. They shall not be interpreted as indicating or implying that the devices or elements must have a particular orientation, or be constructed or operated in a particular orientation; therefore, they do not limit the present disclosure.

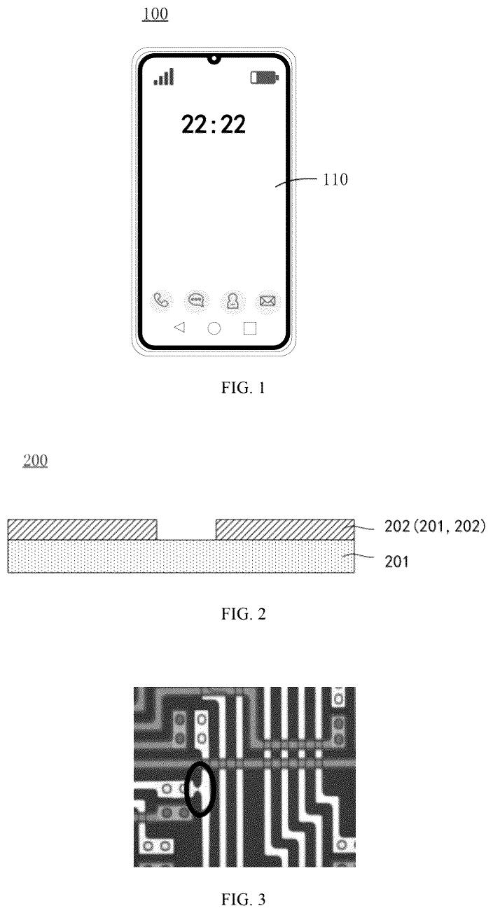

FIG. 1 schematically shows a front-view structure of a display device. As shown in FIG. 1, some embodiments of the disclosure provide a display device 100, wherein the display device 100 may be any device which displays text or images, whether being in motion (for example, videos) or stationary (for example, still images). More explicitly, it is contemplated that the embodiments may be implemented in various electronic devices or associated with various electronic devices such as (but not limited to) a mobile telephone, a wireless device, a personal data assistant (PDA), a hand-held or portable computer, a GPS receiver/navigator, a camera, an MP4 video player, a camcorder, a game console, a watch, a clock, a calculator, a television monitor, a flat-panel display, a computer monitor, an automotive display (for example, an odometer display, and the like), a navigator, a cabin controller and/or display, a display for camera views (for example, a display for a rear-view camera in a vehicle), an electronic photograph, an electronic billboard or signboard, a projector, an architectural structure, packaging and aesthetic structures (for example, a display for an image of a piece of jewelry), and the like. FIG. 1 illustrates the display device 100 with a mobile phone as an example.

The display device 100 includes a display panel 110. The display panel 110 may be a liquid crystal display (abbreviated as LCD) panel; and the display panel 110 may also be a light-emitting diode display panel or a photoluminescent display panel. In the case that the display panel 110 is the light-emitting diode display panel, the light-emitting diode display panel may be an organic light-emitting diode (abbreviated as OLED) display panel or a quantum dot light-emitting diode (abbreviated as QLED) display panel. In the case that the display panel 110 is the photoluminescent display panel, the photoluminescent display device may be a quantum dot photoluminescent display panel.

In some embodiments of the disclosure, the display panel 110 is described with the LCD panel as an example. The display panel 110 includes a driving backplane and a color film substrate which are provided in a face-to-face configuration.

The driving backplane may include a first substrate and a plurality of film layers laminated on the first substrate, wherein the plurality of film layers cooperate with each other to form a driving circuit and a scanning circuit. For example, the plurality of film layers may include a gate layer, an active layer, a source and drain layer, an ITO layer, a passivation layer (abbreviated as PVX), and the like.

The color film substrate may include a second substrate and at least one film layer laminated on the second substrate. For example, at least one film layer includes a color filter, a black matrix, and the like.

An embodiment of the disclosure further provides a mask, wherein the mask is a photolithographic mask which is a pattern motherboard used in a photolithographic process in a micro-nano machining technology. Illustratively, the mask may be a half-tone mask. At least one of the above film layers included in the driving backplane and the color film substrate is prepared and formed by the mask provided in the embodiment of the disclosure.

Hereinafter, the principle of the mask will be described by taking the preparation and formation of the gate layer from the mask provided in the embodiment of the disclosure as an example. After a first metal layer is formed on a first substrate, a photoresist needs to be coated on the first metal layer to obtain a photoresist layer. The photoresist layer is exposed by taking the mask as a template, and then the redundant photoresist is removed so as to transfer a pattern of the mask to the photoresist layer. The first metal layer which is not covered by the photoresist layer is etched to transfer a pattern of the photoresist layer to the first metal layer, so that a plurality of patterned structures are formed in the first metal layer.

FIG. 2 schematically shows a cross-sectional diagram of a mask. As shown in FIG. 2, the mask 200 includes a transparent substrate 201 and a light-shielding layer 202 provided on the transparent substrate 201.

The transparent substrate 201 serves as a framework of the mask 200 and is used for supporting the light-shielding layer 202. At least a partial area of the transparent substrate 201 may transmit light, so that light rays may be transmitted through the transparent substrate 201 to expose the photoresist layer in an exposure process.

Illustratively, the transparent substrate 201 is made of a material with better rigidity and light transmission, such as quartz.

The light-shielding layer 202 is provided on at least one side of the transparent substrate 201 and used for shielding the light rays in the exposure process to prevent the photoresist layer which does not need to be exposed from being irradiated by the light rays.

The light-shielding layer 202 is opaque or has a low light transmittance. Illustratively, the light-shielding layer 202 is made of a metal material, such as chromium.

A plurality of conductive patterns are included in the light-shielding layer 202, and a hollowed-out area is provided between two adjacent conductive patterns. An area opposite to the hollowed-out area in the transparent substrate 201 is light-transmitting, so that the light rays may pass through the transparent substrate 201 and the hollowed-out area to expose the photoresist layer in the exposure process.

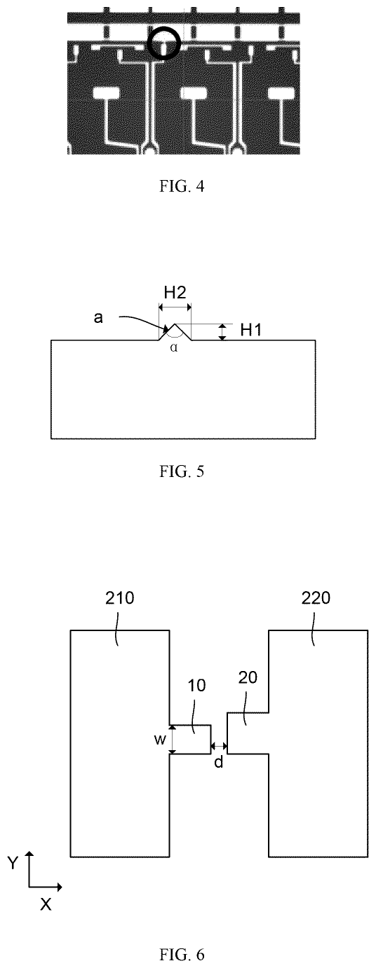

With advancements in technology, the distance between two adjacent patterned structures in the film layer of the display panel has gradually decreased, and correspondingly, the distance between two adjacent conductive patterns in the mask for preparing the film layer has also gradually decreased. When the distance between two adjacent conductive patterns is excessively small, point discharge is likely to occur between the two adjacent conductive patterns, so that the conductive patterns are damaged, thereby affecting the preparation of the patterned structure from the mask. For example, after the point discharge occurs between the two adjacent conductive patterns, a point discharge trace is formed in the hollowed-out area between the two adjacent conductive patterns, and the mask is opaque or semi-transparent in the area where the point discharge trace is formed, which results in that the photoresist layer cannot be sufficiently exposed in the exposure process, so that two patterned structures of the display panel 110 are connected with each other, as shown in FIG. 3 and FIG. 4. Areas in circles in FIG. 3 and FIG. 4 are areas where the two patterned structures are connected with each other.

In the related art, an electrostatic discharge line is provided in the hollowed-out area of the light-shielding layer, one end of the electrostatic discharge line is electrically connected to one conductive pattern, the other end of the electrostatic discharge line is electrically connected to the other conductive pattern, and the two conductive patterns are electrically connected with each other through the electrostatic discharge line, so that potentials of the two conductive patterns are the same, and the occurrence of point discharge between the two conductive patterns is prevented.

However, the photoresist layer is not sufficiently exposed corresponding to a joint of the conductive pattern and the electrostatic discharge line, so that a first residual part a which is not fully exposed is formed on the photoresist layer corresponding to the joint of the conductive pattern and the electrostatic discharge line, as shown in FIG. 5.

As shown in FIG. 5, a height of the first residual part a is H1, a width of the first residual part a is H2, and an included angle of the first residual part a is α (a top angle of a protruding part of the first residue part a as shown in FIG. 5). Generally, the higher the exposure amount of an exposure machine is, and the longer the etching time is, the greater the width H2 of the first residual part a is, the less the height HI of the first residual part a is, and the larger the included angle α of the first residual part a is; and the lower the exposure amount of the exposure machine is, and the shorter the etching time is, the less the width H2 of the first residual part a is, the greater the height H1 of the first residual part a is, and the smaller the included angle α of the first residual part a is.

Illustratively, 0.1 μm≤H1≤1 μm, 0.1 μm≤H2≤2 μm, and 0°≤α≤180°. For example, H1=0.4 μm, H2=0.6 μm, and α=110°; or H1=0.5 μm, H2=0.8 μm, and α=110°.

When a pattern of the first residual part a is transferred to a conductive film layer in the display panel 110, the display panel 110 is likely to be malfunctioned.

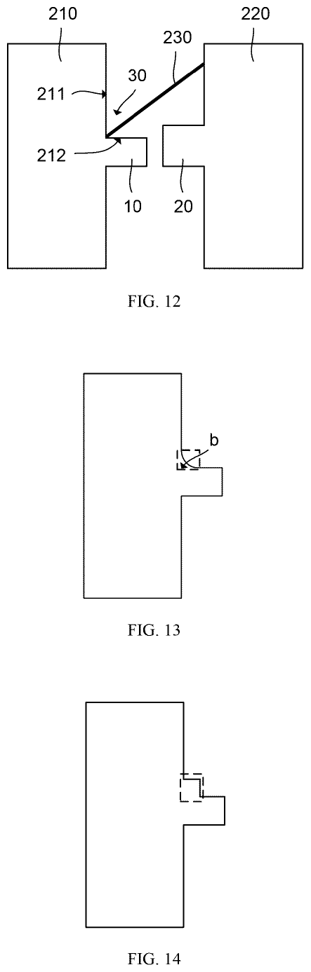

FIG. 12 schematically shows a partial structural diagram of a light-shielding layer. As shown in FIG. 12, the plurality of conductive patterns in the light-shielding layer 202 include a first conductive pattern 210 and a second conductive pattern 220, wherein a hollowed-out area is provided between the first conductive pattern 210 and the second conductive pattern 220. An electrostatic discharge line 230 is positioned in the hollowed-out area, a first end of the electrostatic discharge line 230 is electrically connected to the first conductive pattern 210, and a second end of the electrostatic discharge line 230 is electrically connected to the second conductive pattern 220.

The first conductive pattern 210 and the second conductive pattern 220 are two conductive patterns provided adjacent to each other, and when the electrostatic discharge line 230 is not provided, point discharge is likely to occur between the first conductive pattern 210 and the second conductive pattern 220.

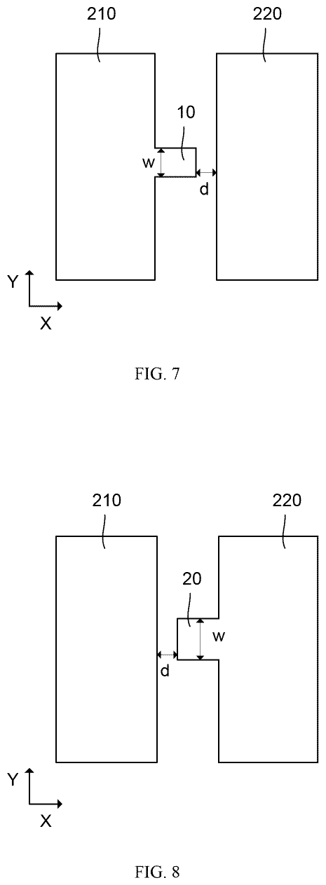

FIG. 6 schematically shows a partial plan diagram of a light-shielding layer, and FIG. 7 schematically shows a partial plan diagram of another light-shielding layer. As shown in FIG. 6 and FIG. 7, the first conductive pattern 210 includes a first conductive portion 10 protruding towards the second conductive pattern 220, the second conductive pattern 220 includes a second conductive portion 20, the first conductive portion 10 is directly opposite to the second conductive portion 20, a minimum distance between the first conductive portion 10 and the second conductive portion 20 is d, and a width of the first conductive portion 10 along a direction perpendicular to the minimum distance between the first conductive portion 10 and the second conductive portion 20 is w; and d≤10 μm, and w≤500 μm.

Illustratively, as shown in FIG. 6, the first conductive pattern 210 includes the first conductive portion 10 protruding towards the second conductive pattern 220, and the second conductive pattern 220 includes the second conductive portion 20 protruding towards the first conductive pattern 210. The distance between the first conductive portion 10 and the second conductive portion 20 is d along the illustrated X-direction, and the size of the first conductive portion 10 is smaller than the size of the second conductive portion 20 and the size of the first conductive portion 10 is w along the illustrated Y-direction. When d≤10 μm and w≤500 μm, point discharge is likely to occur between the first conductive portion 10 and the second conductive portion 20, and the electrostatic discharge line 230 needs to be electrically connected to the first conductive pattern 210 and the second conductive pattern 220.

Illustratively, as shown in FIG. 7, the first conductive pattern 210 includes the first conductive portion 10 protruding towards the second conductive pattern 220, and the second conductive portion 20 which is directly opposite to the first conductive portion 10 in the second conductive pattern 220 is a flat pattern. The distance between the first conductive portion 10 and the second conductive portion 20 is d along the illustrated X-direction, and the size of the first conductive portion 10 is w along the illustrated Y-direction. When d≤10 μm and w≤500 μm, point discharge is likely to occur between the first conductive portion 10 and the second conductive portion 20, and the electrostatic discharge line 230 needs to be electrically connected to the first conductive pattern 210 and the second conductive pattern 220.

FIG. 8 schematically shows a plan diagram of another light-shielding layer. Illustratively, as shown in FIG. 8, the second conductive pattern 220 includes the second conductive portion 20 protruding towards the first conductive pattern 210, and the first conductive portion 10 which is directly opposite to the second conductive portion 20 in the first conductive pattern 210 is a flat pattern. The distance between the first conductive portion 10 and the second conductive portion 20 is d along the illustrated X-direction, and the size of the second conductive portion 20 is w along the illustrated Y-direction. When d≤10 μm and w≤500 μm, point discharge is likely to occur between the first conductive portion 10 and the second conductive portion 20, and the electrostatic discharge line 230 needs to be electrically connected to the first conductive pattern 210 and the second conductive pattern 220.

For convenience of description, only the first conductive pattern 210 and the second conductive pattern 220 shown in FIG. 6 will be described as an example.

The electrostatic discharge line 230 is positioned in the hollowed-out area, and may be electrically connected to the first conductive pattern 210 and the second conductive pattern 220.

Illustratively, the electrostatic discharge line 230 is provided in the same layer as the first conductive pattern 210 and the second conductive pattern 220. Being provided in the same layer means that the electrostatic discharge line 230, the first conductive pattern 210, and the second conductive pattern 220 are formed in the same patterning process. Of course, the electrostatic discharge line 230 may also be provided in a different layer from the first conductive pattern 210 and the second conductive pattern 220, which is not limited in the embodiment of the disclosure.

Since the electrostatic discharge line 230 has the function of being electrically connected to the first conductive pattern 210 and the second conductive pattern 220 to balance charges in the first conductive pattern 210 and the second conductive pattern 220, it is not desirable to transfer the pattern of the electrostatic discharge line 230 to the photoresist layer. Therefore, on the premise of ensuring the charge discharge capability of the electrostatic discharge line 230, it is necessary to reduce the line width of the electrostatic discharge line 230 as much as possible, so that the exposure machine cannot transfer the pattern of the electrostatic discharge line 230 to the photoresist layer.

Illustratively, the line width of the electrostatic discharge line 230 is less than the minimum resolution of the exposure machine, for example, the line width of the electrostatic discharge line 230 is L, and 0.5 μm≤L≤1.0 μm.

The line widths of the electrostatic discharge line 230 at various positions may be the same or may be different. Illustratively, when the line widths of the electrostatic discharge line 230 at various positions are different, the minimum line width of the electrostatic discharge line 230 is greater than or equal to 0.5 μm, and the maximum line width of the electrostatic discharge line 230 is less than or equal to 1 μm.

The electrostatic discharge line 230 may be a straight line or may be a broken line or a curved line.

When the electrostatic discharge line 230 is the straight line, the electrostatic discharge line 230 occupies less space. Illustratively, when the distance between the first conductive portion 10 and the second conductive portion 20 is relatively small, the electrostatic discharge line 230 may be provided as the straight line.

When the pattern of the mask 200 is transferred to the conductive film layer, a first conductive structure is generated corresponding to the first conductive pattern 210 and a second conductive structure is generated corresponding to the second conductive pattern 220 in the conductive film layer, wherein the first conductive structure is likely to form a first sharp angle corresponding to the joint of the first conductive pattern 210 and the electrostatic discharge line 230, and the second conductive structure forms a second sharp angle corresponding to the joint of the second conductive pattern 220 and the electrostatic discharge line 230. When the electrostatic discharge line 230 is the broken line or the curved line, the first end and the second end of the electrostatic discharge line 230 are not directly opposite to each other, so that the formed first sharp angle and second sharp angle are also not directly opposite to each other, thereby reducing the probability of occurrence of point discharge between the first sharp angle and the second sharp angle.

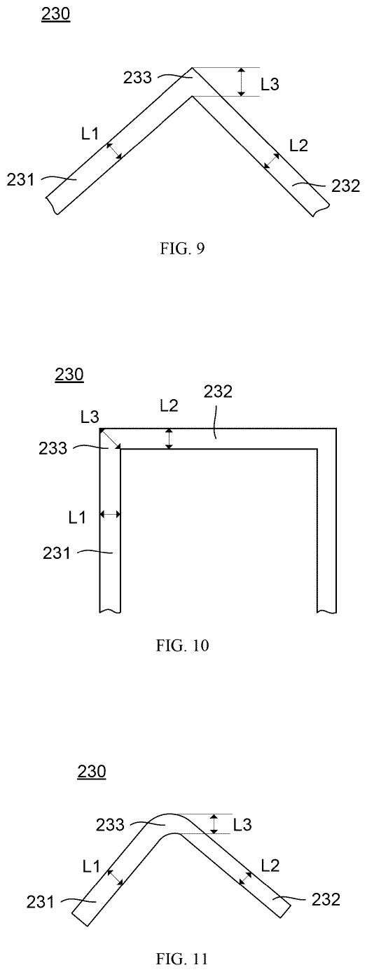

When the electrostatic discharge line 230 is the broken line or the curved line, the electrostatic discharge line 230 may include one tum or may include a plurality of tums. FIG. 9 schematically shows a plan diagram of an electrostatic discharge line, and as shown in FIG. 9, the electrostatic discharge line 230 includes one turn. FIG. 10 schematically shows a plan diagram of another electrostatic discharge line, and as shown in FIG. 10, the electrostatic discharge line 230 includes two turns.

With continued reference to FIG. 9 and FIG. 10, the electrostatic discharge line 230 may include a first wire 231, a second wire 232, and a transition line 233 connecting the first wire 231 to the second wire 232, wherein the first wire 231 extends along a first direction, the second wire 232 extends along a second direction, and the first direction intersects the second direction. As can be seen from FIG. 9 and FIG. 10, a line width L3 of the transition line 233 is greater than a line width L1 of the first wire 231 and a line width L2 of the second wire 232. Since the maximum line width of the electrostatic discharge line 230 needs to be less than or equal to 1 μm, namely, L3≤1 μm, L1 and L2 need to be further decreased on the basis of L3, so that selectable ranges of L1 and L2 are narrowed.

Therefore, the line width L3 of the transition line 233 may be equal to the line width L1 of the first wire 231 and the line width L2 of the second wire 232, so that the selectable ranges of the line width L1 of the first wire 231, the line width L2 of the second wire 232, and the line width L3 of the transition line 233 are larger.

FIG. 11 schematically shows a plan diagram of another electrostatic discharge line. Illustratively, as shown in FIG. 11, the transition line 233 is a circular arc, and the transition line 233 smoothly transitions with the first wire 231 and the second wire 232, so that the line width L1 of the first wire 231, the line width L2 of the second wire 232, and the line width L3 of the transition line 233 are equal.

Of course, the transition line 233 may also be of other structures, as long as the line widths L3 of the transition line 233 at various positions are equal to each other and equal to the line width L1 of the first wire 231 and the line width L2 of the second wire 232.

With continued reference to FIG. 12, one side of the first conductive pattern 210 facing the second conductive pattern 220 includes a first edge 211 and a second edge 212, and the first edge 211 and the second edge 212 are connected to form a first concave angle 30. The first concave angle 30 refers to an angle which is recessed towards the interior of the first conductive pattern 210.

When the photoresist layer is exposed by the exposure machine through the mask 200, an area corresponding to the first concave angle 30 in the photoresist layer is often not exposed sufficiently, and a desired concave angle cannot be formed. FIG. 13 schematically shows a patterned structure formed by transferring a first conductive pattern to the photoresist layer. Illustratively, as shown in FIG. 13, the patterned structure formed by the photoresist layer is not completely etched corresponding to the area of the first concave angle 30 to form a second residual part b (an area in a dashed box in the figure).

In view of this, as shown in FIG. 12, in the embodiment of the present disclosure, the first end of the electrostatic discharge line 230 is electrically connected to the first concave angle 30.

A patterned structure formed by transferring the first conductive pattern 210 to the photoresist layer is a first patterned structure. Since the electrostatic discharge line 230 is electrically connected to the first concave angle 30, a first residual structure a formed corresponding to a joint of the electrostatic discharge line 230 and the first conductive pattern 210 in the first patterned structure is positioned in an area opposite to the first concave angle 30 in the first patterned structure; and due to the exposure characteristic inherent to the first concave angle 30, a second residual part b may be formed in the area opposite to the first concave angle 30 in the first patterned structure. Both the first residual part a and the second residual part b are positioned in the area opposite to the first concave angle 30 in the first patterned structure, so that at least partial areas of the first residual part a and the second residual part b are overlapped with each other, thereby increasing a quantity of the residual parts which are not completely exposed in the photoresist layer, and causing the pattern of the first patterned structure to deviate from the pattern of the first conductive pattern 210.

The first end of the electrostatic discharge line 230 may extend along an angular bisector of the first concave angle 30, so that the electrostatic discharge line 230 is equidistant from the first edge 211 and the second edge 212, and the exposure amounts on two sides of the electrostatic discharge line 230 are substantially consistent.

FIG. 14 schematically shows a first patterned structure formed after a first end of the electrostatic discharge line is connected to a first concave angle. As shown in FIG. 14, when the first end of the electrostatic discharge line 230 is electrically connected to the first concave angle 30, the first patterned structure may form a redundant structure (an area in a dashed box in the figure).

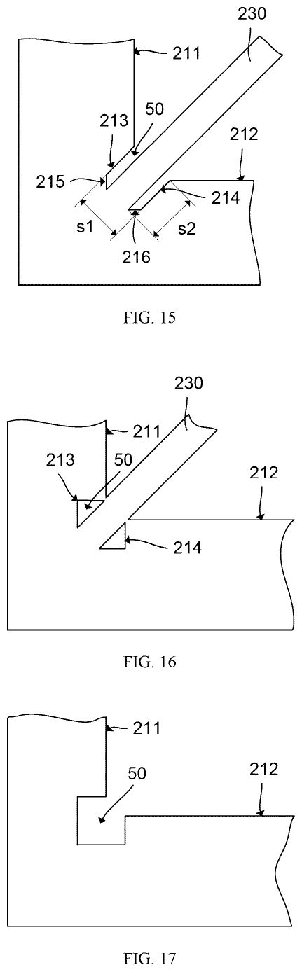

FIG. 15 schematically shows a partial structural diagram of the first conductive pattern. As shown in FIG. 15, the first concave angle 30 may be provided with a first notch 50, a partial area of the first end of the electrostatic discharge line 230 is positioned in the first notch 50, and a gap is provided between the electrostatic discharge line 230 and a side edge of the first notch 50. In this way, the light transmission at the joint of the electrostatic discharge line 230 and the first concave angle 30 may be improved, thereby enabling the photoresist layer to be exposed more sufficiently, decreasing the size of the first residual part a or eliminating the first residual part, and enabling the first patterned structure to be closer to the pattern of the first conductive structure 210.

The size of the first notch 50 along a direction of the line width of the electrostatic discharge line 230 is s1, and the size of the first notch 50 along a routing direction of the first end of the electrostatic discharge line 230 is s2. Illustratively, 0.5 μm≤s1≤2.0 μm, 0.5 μm≤s2 ≤2.0 μm.

A partial or entire area of the first notch 50 is positioned on sides of the first edge 211 and the second edge 212 away from the hollow-out area. That is, the first notch 50 is positioned on an inner side of the first concave angle 30 facing the first conductive pattern 210, so that the exposure at the first concave angle 30 is more sufficient, thereby reducing or eliminating the first residual part a which is opposite to the first concave angle 30 and positioned in the first patterned structure.

The first notch 50 may be symmetrically provided relative to the angular bisector of the first concave angle 30, so that the first concave angle 30 is exposed more uniformly along two sides of the angular bisector.

With continued reference to FIG. 15, the side edge of the first notch 50 includes a first side edge 213 and a second side edge 214, the first side edge 213 and the second side edge 214 are provided parallel and opposite to each other, and the first end of the electrostatic discharge line 230 is positioned between the first side edge 213 and the second side edge 214. The first notch 50 further includes a first bottom edge 215 and a second bottom edge 216, the first bottom edge 215 is connected to the first side edge 213 and the electrostatic discharge line 230, the first bottom edge 215 is parallel to the first edge 211, the second bottom edge 216 is connected to the second side edge 214 and the electrostatic discharge line 230, and the second bottom edge 216 is parallel to the second edge 212, so that the exposure at the first concave angle 30 is more sufficient, thereby reducing or eliminating the first residual part a which is opposite to the first concave angle 30 and positioned in the first patterned structure.

FIG. 16 schematically shows a partial structural diagram of the first conductive pattern. As shown in FIG. 16, the first notch 50 includes the first side edge 213 and the second side edge 214, a first gap is enclosed by the first side edge 213 and the electrostatic discharge line 230, a second gap is enclosed by the second side edge 214 and the electrostatic discharge line 230, and the first gap and/or the second gap is not communicated with the hollow-out area, so that the exposure at the first concave angle 30 is more sufficient, thereby reducing or eliminating the first residual part a which is opposite to the first concave angle 30 and positioned in the first patterned structure.

FIG. 17 shows a structural diagram of the first conductive pattern without the electrostatic discharge line connected. Illustratively, as shown in FIG. 17, the first notch 50 is quadrilateral, and a diagonal line of the first notch 50 coincides with the angular bisector of the first concave angle 30. When the electrostatic discharge line 230 extends along the angular bisector of the first concave angle 30, the exposure amounts on two sides of the electrostatic discharge line 230 are substantially consistent.

A partial or entire area of the first notch 50 may also be positioned on sides of the first edge 211 and the second edge 212 close to a transparent area, so that the preparation of the first notch 50 is easier.

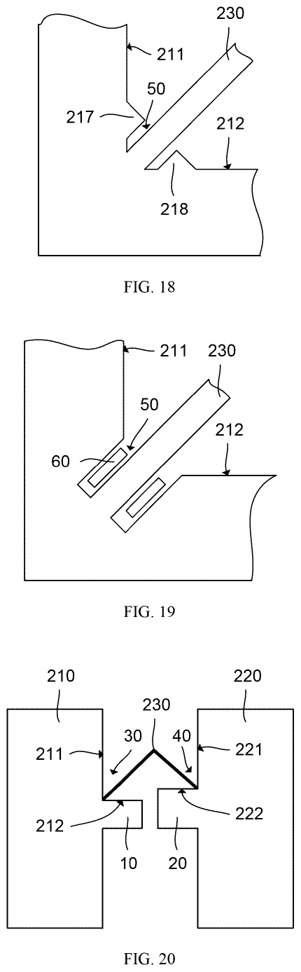

FIG. 18 schematically shows a partial structural diagram of the first conductive pattern. As shown in FIG. 18, the first edge 211 is provided with a first protrusion 217 protruding towards the hollow-out area, the second edge 212 is provided with a second protrusion 218 protruding towards the hollow-out area, and the first notch 50 is enclosed by the first protrusion 217 and the second protrusion 218.

Illustratively, the first protrusion 217 and the second protrusion 218 are right triangles, one side of the first protrusion 217 is parallel to the electrostatic discharge line 230, and one side of the second protrusion 218 is parallel to the electrostatic discharge line 230. The first protrusion 217 and the second protrusion 218 may be equal in size.

FIG. 19 schematically shows a partial structural diagram of the first conductive pattern. As shown in FIG. 19, a light-shielding portion 60 may be provided in the gap, and the light-shielding portion 60 is island-shaped in the gap.

Illustratively, the gap is provided between the light-shielding portion 60 and the electrostatic discharge line 230 and each side of the first notch 50, so that light rays may be irradiated to the photoresist layer below through the gaps, thereby increasing the exposure amount of the photoresist layer.

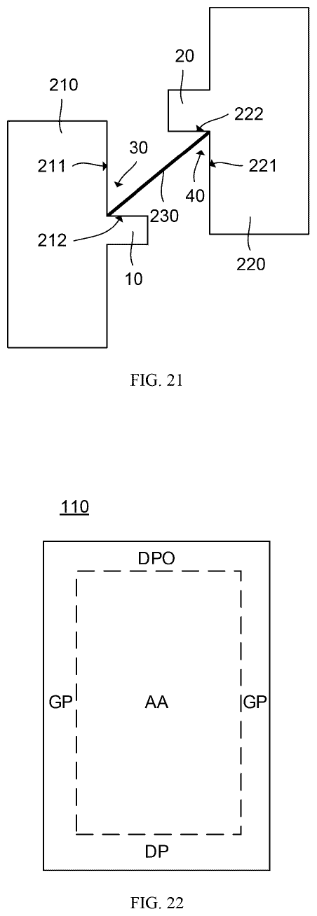

FIG. 20 schematically shows a partial plan diagram of another light-shielding layer, and FIG. 21 schematically shows a partial plan diagram of another light-shielding layer. As shown in FIG. 20 and FIG. 21, one side of the second conductive pattern 220 facing the first conductive pattern 210 may include a third edge 221 and a fourth edge 222, the third edge 221 and the fourth edge 222 are connected to form a second concave angle 40, and the second end of the electrostatic discharge line 230 may be electrically connected to the second concave angle 40.

A patterned structure formed by transferring the second conductive pattern 220 to the photoresist layer is a second patterned structure. The second end of the electrostatic discharge line 230 is electrically connected to the second concave angle 40 to reduce the quantity of residual parts on the second patterned structure, so that the pattern of the second patterned structure is closer to the pattern of the second conductive pattern 220.

When the first end of the electrostatic discharge line 230 is electrically connected to the first concave angle 30 and the second end of the electrostatic discharge line 230 is electrically connected to the second concave angle 40, the electrostatic discharge line 230 may be a broken line (as shown in FIG. 20), and the electrostatic discharge line 230 may also be a straight line (as shown in FIG. 21);
wherein a linear distance between the first concave angle 30 and the second concave angle 40 may be greater than or equal to 10 μm, so as to prevent point discharge from occurring between conductive structures corresponding to the first concave angle 30 and the second concave angle 40 in the film layer of the display panel 110.

The second concave angle 40 may be provided with a second notch, and the size and structure of the second notch may be the same as those of the first notch 50 or may be different from those of the first notch 50, which will not be described in detail herein.

FIG. 22 schematically shows a display panel. As shown in FIG. 22, the display panel 110 includes a display area AA and a non-display area surrounding the display area.

Illustratively, the non-display area includes a data signal input side DP positioned below the display area, scanning signal input sides GP positioned on a left side and a right side of the display area, and an opposite side DPO positioned above the display area.

A plurality of pixel electrodes, a plurality of gate lines and a plurality of data lines are provided in the display area AA, the plurality of gate lines are provided parallel to each other, the plurality of data lines are provided parallel to each other, and two adjacent pixel electrodes are independently provided and are relatively distant from each other. Therefore, point discharge is not likely to occur in an area corresponding to the display area AA in the mask 200.

On the GP side, a scanning circuit and a corresponding signal routing line are provided, and the signal lines are complex and dense. Therefore, the point discharge is likely to occur in an area corresponding to the GP side in the mask 200, and the electrostatic discharge line 230 needs to be provided in the area corresponding to the GP side in the mask 200. In view of this, the electrostatic discharge line 230 may be provided close to an edge of the mask 200.

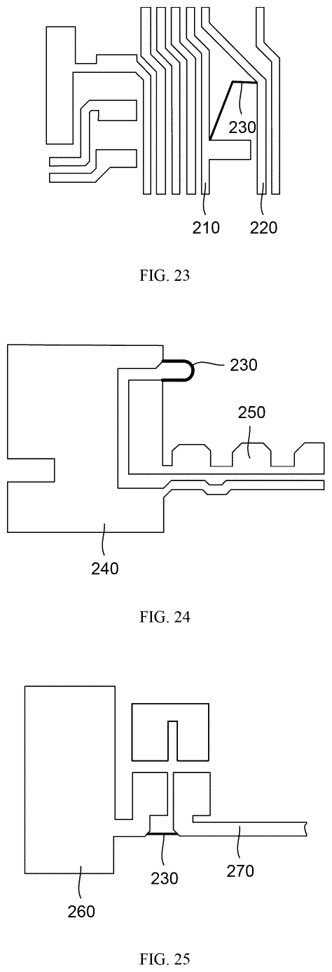

FIG. 23 schematically shows a partial structure of an area corresponding to a GP side in the light-shielding layer, lines extending along a vertical direction in FIG. 23 respectively correspond to signal lines in the scanning circuit, and as shown in FIG. 23, the electrostatic discharge line 230 may be provided between the first conductive pattern 210 and the second conductive pattern 220 corresponding to two adjacent signal lines.

FIG. 24 schematically shows a partial structure of an area corresponding to a scanning circuit output line in the light-shielding layer. In FIG. 23, a third conductive pattern 240 corresponds to a Vcom line, a fourth conductive pattern 250 corresponds to an output line, and the electrostatic discharge line is provided between the third conductive pattern 240 and the fourth conductive pattern 250.

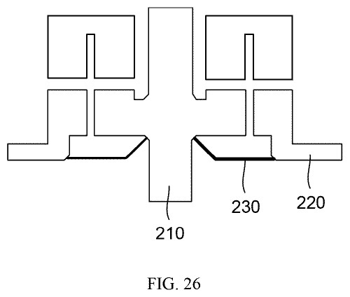

FIG. 25 schematically shows a partial structure diagram of an area corresponding to a DP side in the light-shielding layer. In FIG. 25, a fifth conductive pattern 260 corresponds to the Vcom line, and the fifth conductive pattern 260 is electrically connected to an adjacent sixth conductive pattern 270 through the electrostatic discharge line. FIG. 26 schematically shows a partial structure diagram of an area corresponding to a DPO side in the light-shielding layer. In FIG. 26, the first conductive pattern 210 corresponds to the Vcom line, the second conductive pattern 220 corresponds to a Data line, and the electrostatic discharge line 230 is provided between the first conductive pattern 210 and the second conductive pattern 220, wherein the electrostatic discharge line 230 is electrically connected to the concave angle of the first conductive pattern.

The above descriptions are merely specific implementations of the present disclosure; however, the protection scope of the present disclosure is not limited thereto. Any person skilled in the art can readily conceive of variations or substitutions within the technical scope disclosed by the present disclosure, and all such variations or substitutions shall fall within the protection scope of the present disclosure. Therefore, the protection scope of the present disclosure shall be subject to the protection scope of the claims.

1. A mask, comprising:
a transparent substrate; and
a light-shielding layer provided on one side of the transparent substrate, and comprising a first conductive pattern, a second conductive pattern, and an electrostatic discharge line, wherein a hollow-out area is provided between the first conductive pattern and the second conductive pattern, and the electrostatic discharge line is positioned in the hollow-out area; and one side of the first conductive pattern facing the second conductive pattern comprises a first edge and a second edge, the first edge and the second edge are connected to form a first concave angle, a first end of the electrostatic discharge line is electrically connected to the first concave angle, and a second end of the electrostatic discharge line is electrically connected to the second conductive pattern.

2. The mask according to claim 1, wherein the first end of the electrostatic discharge line extends along an angular bisector of the first concave angle.

3. The mask according to claim 1, wherein the first concave angle is provided with a first notch, a partial area of the first end of the electrostatic discharge line is positioned in the first notch, and a gap is provided between the electrostatic discharge line and a side edge of the first notch.

4. The mask according to claim 3, wherein a partial or entire area of the first notch is positioned on sides of the first edge and the second edge away from the hollow-out area.

5. The mask according to claim 4, wherein the side edge of the first notch comprises a first side edge and a second side edge, the first side edge and the second side edge are provided parallel and opposite to each other, and the first end of the electrostatic discharge line is positioned between the first side edge and the second side edge; and
the first notch further comprises a first bottom edge and a second bottom edge, the first bottom edge is connected to the first side edge and the electrostatic discharge line, the first bottom edge is parallel to the first edge, the second bottom edge is connected to the second side edge and the electrostatic discharge line, and the second bottom edge is parallel to the second edge.

6. The mask according to claim 4, wherein the first notch comprises the first side edge and the second side edge, a first gap is enclosed by the first side edge and the electrostatic discharge line, a second gap is enclosed by the second side edge and the electrostatic discharge line, and the first gap and/or the second gap is not communicated with the hollow-out area.

7. The mask according to claim 6, wherein the first notch is quadrilateral, and a diagonal line of the first notch coincides with an angular bisector of the first concave angle.

8. The mask according to claim 3, wherein a partial or entire area of the first notch is positioned on sides of the first edge and the second edge close to a transparent area.

9. The mask according to claim 8, wherein the first edge is provided with a first protrusion protruding towards the hollow-out area, the second edge is provided with a second protrusion protruding towards the hollow-out area, and the first notch is enclosed by the first protrusion and the second protrusion.

10. The mask according to claim 3, wherein the first notch is symmetrically provided relative to an angular bisector of the first concave angle.

11. The mask according to claim 3, wherein a light-shielding portion is provided in the gap, and the light-shielding portion is island-shaped in the gap.

12. The mask according to claim 1, wherein the electrostatic discharge line comprises a first wire, a second wire, and a transition line connecting the first wire to the second wire, the first wire extends along a first direction, the second wire extends along a second direction, the first direction intersects the second direction, and a line width of the transition line is equal to a line width of the first wire and the second wire.

13. The mask according to claim 12, wherein the transition line is an arc.

14. The mask according to claim 1. wherein one side of the second conductive pattern facing the first conductive pattern includes a third edge and a fourth edge, the third edge and the fourth edge are connected to form a second concave angle, and the second end of the electrostatic discharge line is electrically connected to the second concave angle.

15. The mask according to claim 14, wherein a straight-line distance between the first concave angle and the second concave angle is greater than or equal to 10 μm.

16. The mask according to claim 1. wherein a line width of the electrostatic discharge line is L, and 0.5 μm≤L≤1.0 μm.

17. The mask according to claim 1, wherein the first conductive pattern comprises a first conductive portion protruding towards the second conductive pattern, the second conductive pattern comprises a second conductive portion, the first conductive portion is directly opposite to the second conductive portion, a minimum distance between the first conductive portion and the second conductive portion is d, and a width of the first conductive portion along a direction perpendicular to the minimum distance between the first conductive portion and the second conductive portion is w; and
d≤10 μm, and w≤500 μm.

18. The mask according to claim 1. wherein the electrostatic discharge line is provided close to an edge of the mask.

19. A display panel, comprising a plurality of film layers, wherein at least one of the plurality of film layers is fabricated by photolithography using the mask according to claim 1.
